(19) United States
(12) Patent Application Publication
(10) Pub. No.: US 2024/0329333 A1
(43) Pub. Date: Oct. 3, 2024

(54) CO-PACKAGING OF PHOTONIC & ELECTRONIC INTEGRATED CIRCUIT DIE

(71) Applicant: Intel Corporation, Santa Clara, CA (US)

(72) Inventors: Robert May, Chandler, AZ (US); Bai Nie, Chandler, AZ (US); Changhua Liu, Chandler, AZ (US); Hiroki Tanaka, Gilbert, AZ (US); Kristof Darmawikarta, Chandler, AZ (US); Lilia May, Chandler, AZ (US); Shriya Seshadri, Chandler, AZ (US); Srinivas Pietambaram, Chandler, AZ (US); Tarek Ibrahim, Mesa, AZ (US)

(73) Assignee: Intel Corporation, Santa Clara, CA (US)

(21) Appl. No.: 18/129,690

(22) Filed: Mar. 31, 2023

(51) Int. Cl. G02B 6/42; G02B 6/13; H01L 25/065; H01L 25/16

(52) U.S. Cl. CPC G02B 6/4202; G02B 6/13; H01L 25/0655; H01L 25/167; G02B 2006/12038

(57) ABSTRACT

Multi-die packages including both photonic and electric integrated circuit (IC) die interconnected to each other through a routing structure built-up on a glass substrate. A glass preform comprising an optical waveguide may also be attached to the routing structure. A plurality of electrical IC (EIC) die may be arrayed over the routing structure along with a plurality of photonic IC (PIC). Each PIC may be coupled to an optical waveguide within the glass preform. Conductive vias may extend through the glass substrate and be further coupled with a host substrate. The host substrate may comprise glass and an optical waveguide embedded within the glass. A vertical coupler may be attached to the host substrate to optically couple the host substrate to the optical waveguide within the glass preform of the multi-die package. Many of the multi-die packages may be arrayed over a routing structure on the host substrate.

### BACKGROUND

In electronics manufacturing, IC packaging is a stage of semiconductor device fabrication in which an IC that has been monolithically fabricated on a chip (or die) comprising a semiconducting material is assembled into a “package” that can protect the IC chip from physical damage and communicatively connect the IC to a scaled host component, such as an organic package substrate, or a printed circuit board. Multiple chips can be similarly co-assembled, for example, into a multi-die package (MCP).

Co-packaging of photonic integrated circuit (PIC) die and electrical IC (EIC) die introduces additional challenges with some architectures proving to be unsuitable for high volume manufacturing and/or suffering high optical signal loss, for example stemming from active alignment of the components. Some of these solutions are also unable to meet compute density requirements for future technologies.

Alternative architectures for PIC and EIC co-packaging would therefore be commercially advantageous as enabling higher bandwidth optical and electrical interconnection of multiple IC die.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements. In the figures:

FIG. 1 illustrates a flow diagram of methods for forming a multi-die device structure including electronic IC (EIC) die and photonic IC (PIC) die interconnected to each other through a substrate routing structure, in accordance with some embodiments;

FIGS. 2A, 2B, 2C, 2D, 2E, 2F, 2G and 2H illustrate cross-sectional views of a multi-die device structure evolving to include EIC die as some operations in the methods illustrated in FIG. 1 are performed, in accordance with some embodiments;

FIG. 3 illustrates a flow diagram of methods for forming an optical waveguide within a glass preform suitable for a multi-die device structure including a PIC, in accordance with some embodiments;

FIGS. 4A, 4B and 4C illustrate cross-sectional views of a glass preform evolving to include an optical waveguide as some operations in the methods illustrated in FIG. 3 are performed, in accordance with some embodiments;

FIGS. 5A, 5B, 5C, and 5D illustrate cross-sectional views of the multi-die device structure illustrated in FIG. 2H further evolving to include a glass preform with an optical waveguide and a PIC as some operations in the methods illustrated in FIG. 1 are performed, in accordance with some embodiments;

FIG. 5E is a plan view of the multi-die device structure illustrated in FIG. 5D, in accordance with some embodiments;

FIG. 6 illustrates a system including one of the multi-die device structures illustrated in FIG. 5E attached to a host component with solder features, in accordance with some embodiments;

FIG. 7 illustrates a flow diagram of methods for optically and electrically coupling a plurality of the multi-die device structures illustrated in FIG. 5E to a secondary substrate comprising glass, in accordance with some embodiments;

FIG. 8A illustrates a plan view of a secondary substrate, in accordance with some embodiments;

FIG. 8B illustrates a cross-sectional view of a portion of a secondary substrate illustrated in FIG. 8A, in accordance with some embodiments;

FIG. 9A illustrates a plan view of a plurality of the multi-die device structures illustrated in FIG. 5E attached to the secondary substrate illustrated in FIG. 8A, in accordance with some embodiments;

FIG. 9B illustrates a cross-sectional view of the plurality of the multi-die device structures and secondary substrate illustrated in FIG. 9A, in accordance with some embodiments;

FIG. 10 illustrates a plan view of a plurality of the multi-die device structures illustrated in FIG. 8A attached to a host component, in accordance with an embodiment;

FIG. 11 illustrates a system including the multi-die device structures illustrated in FIG. 9A or FIG. 10 further attached to a host component with solder features, in accordance with some embodiments;

FIG. 12 illustrates a mobile computing platform and a data server machine employing multi-die device structures comprising PIC and EIC die co-packaged in accordance with some embodiments; and

FIG. 13 is a functional block diagram of an electronic computing device, in accordance with some embodiments.

### DETAILED DESCRIPTION OF EXEMPLARY EMBODIMENTS

Embodiments are described with reference to the enclosed figures. While specific configurations and arrangements are depicted and discussed in detail, this is done for illustrative purposes only. Persons skilled in the relevant art will recognize that other configurations and arrangements are possible without departing from the spirit and scope of the description. It will be apparent to those skilled in the relevant art that techniques and/or arrangements described herein may be employed in a variety of other systems and applications other than what is described in detail herein.

Reference is made in the following detailed description to the accompanying drawings, which form a part hereof and illustrate exemplary embodiments. Further, it is to be understood that other embodiments may be utilized and structural and/or logical changes may be made without departing from the scope of claimed subject matter. It should also be noted that directions and references, for example, up, down, top, bottom, and so on, may be used merely to facilitate the description of features in the drawings. Therefore, the following detailed description is not to be taken in a limiting sense and the scope of claimed subject matter is defined solely by the appended claims and their equivalents.

In the following description, numerous details are set forth. However, it will be apparent to one skilled in the art, that embodiments may be practiced without these specific details. In some instances, well-known methods and devices are shown in block diagram form, rather than in detail, to avoid obscuring the embodiments. Reference throughout this specification to “an embodiment” or “one embodiment” or “some embodiments” means that a particular feature, structure, function, or characteristic described in connection with the embodiment is included in at least one embodiment. Thus, the appearances of the phrase “in an embodiment” or “in one embodiment” or “some embodiments” in various places throughout this specification are not necessarily referring to the same embodiment. Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

As used in the description and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items.

The terms “coupled” and “connected,” along with their derivatives, may be used herein to describe functional or structural relationships between components. These terms are not intended as synonyms for each other. Rather, in particular embodiments, “connected” may be used to indicate that two or more elements are in direct physical, optical, or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause-and-effect relationship).

The terms “over,” “under,” “between,” and “on” as used herein refer to a relative position of one component or material with respect to other components or materials where such physical relationships are noteworthy. For example, in the context of materials, one material or layer over or under another may be directly in contact or may have one or more intervening materials or layers. Moreover, one material between two materials or layers may be directly in contact with the two materials/layers or may have one or more intervening materials/layers. In contrast, a first material or layer “on” a second material or layer is in direct contact with that second material/layer. Similar distinctions are to be made in the context of component assemblies.

As used throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C.

Unless otherwise specified in the specific context of use, the term “predominantly” means more than 50%, or more than half. For example, a composition that is predominantly a first constituent means more than half of the composition is the first constituent (e.g., <50 at. %). The term “primarily” means the most, or greatest, part. For example, a composition that is primarily a first constituent means the composition has more of the first constituent than any other constituent. A composition that is primarily first and second constituents means the composition has more of the first and second constituents than any other constituent. The term “substantially” means there is only incidental variation. For example, composition that is substantially a first constituent means the composition may further include <1% of any other constituent. A composition that is substantially first and second constituents means the composition may further include <1% of any constituent substituted for either the first or second constituent.

Co-packaged device structures including interconnected PIC die(s) and EIC die(s) are described herein. A first, or primary, electrical routing structure comprising redistribution layer (RDL) metallization on at least one side of a primary substrate may electrically interconnect the co-packaged IC dies to each other and may further couple the co-packaged IC dies to a host component. A glass preform comprising one or more primary optical waveguides may be assembled upon the primary substrate, to optically couple together multiple co-packaged PIC die and/or optically couple each PIC die to the host component. One or more passive devices may also be assembled upon the primary substrate. For example, a coupling capacitor may be embedded within the primary substrate.

In some further embodiments, the host component is a secondary substrate that comprises one or more secondary optical waveguides. At least one side of the secondary substrate may further comprise a secondary electrical routing structure comprising RDL metallization features. The primary substrate may be assembled with the secondary substrate to electrically interconnect the primary and secondary electrical routing structures. An optical coupler may be assembled with the secondary substrate to optically interconnect the primary and secondary optical waveguides through the optical coupler. As described further below, the secondary substrate may comprise a glass bulk layer or slab, within which the secondary optical waveguide is defined. In some exemplary embodiments, a plurality of co-packaged device structures is assembled, for example at a panel level, upon one secondary substrate. Once fully assembled, each multi-die multi-substrate electro-optical device assembly may be attached to a host component, such as a printed circuit board (PCB), a package interposer, or any other component suitable as a next level of system integration.

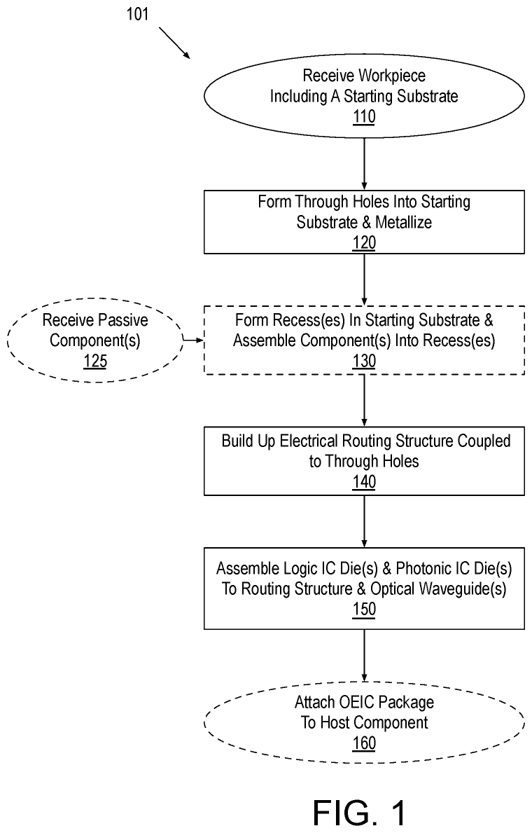

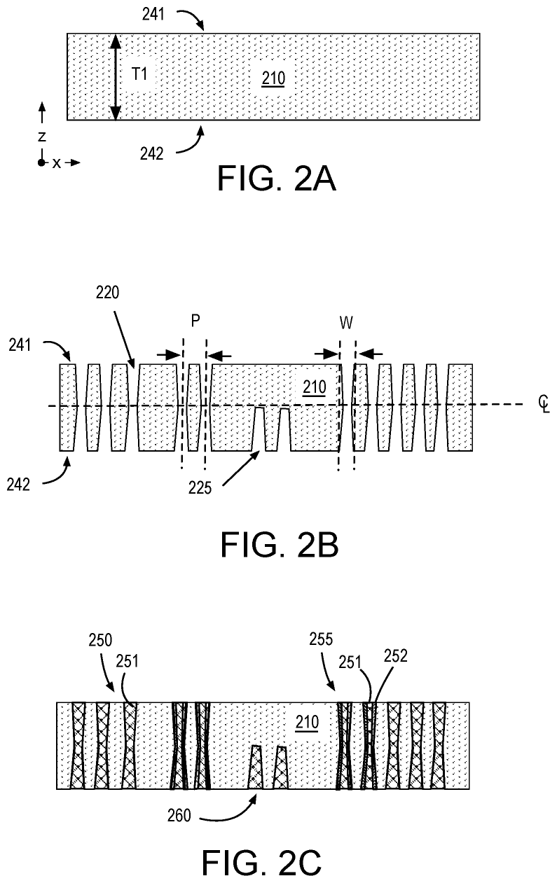

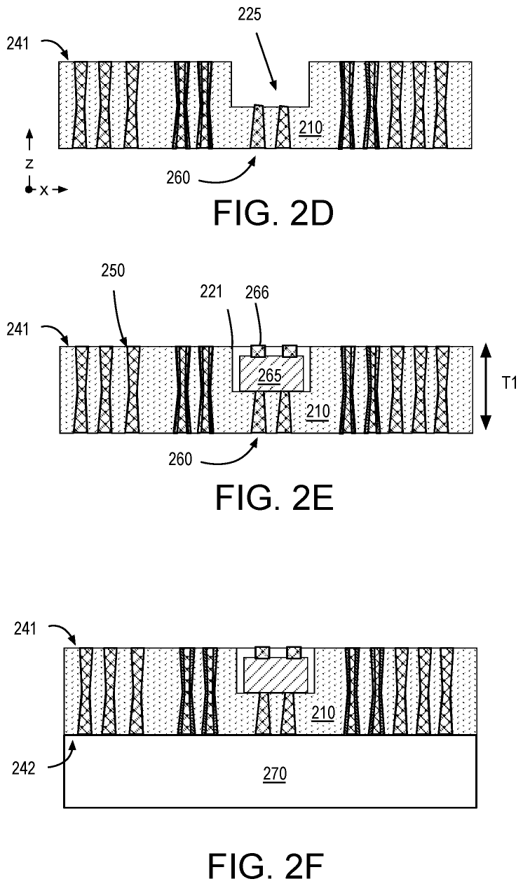

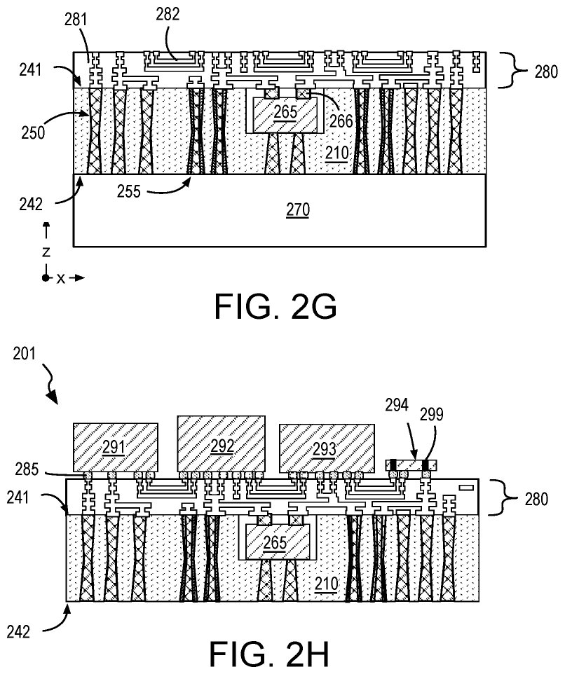

A variety of fabrication methods may be practiced to form multi-die device structures having one or more of the features or attributes described herein. FIG. 1 illustrates a flow diagram of methods 101 for forming a device structure including at least one electronic IC (EIC) die and at least one photonic IC (PIC) die, in accordance with some embodiments. FIG. 2A-2H illustrate cross-sectional views of a multi-die device structure evolving to include EIC die as some operations in the methods 101 are performed, in accordance with some exemplary embodiments.

As shown in FIG. 1, methods 101 begin at input 110 with the receipt of a workpiece including a starting substrate prepared upstream of methods 101. The starting substrate may comprise one or more materials upon which electrical routing structures may be formed. FIG. 2A illustrates an exemplary starting substrate 210 that is a slab of bulk glass. Co-packaged device structures may be advantageously fabricated upon such a glass preform as flatness and/or thickness control is superior to that of starting substrates based on organic materials (e.g., epoxy) and costs are lower than for monocrystalline materials (e.g., silicon). Starting substrate 210 is advantageously predominantly silica (e.g., silicon and oxygen) and substantially homogeneous. Any dopants (e.g., boron, phosphorus) may be present in starting substrate 210 (e.g., borosilicate glass, etc.) as embodiments herein are not limited in this respect. Although not depicted, one or more material may clad either or both of the front-side surface 241 or back-side surface 242. Exemplary cladding materials include silicon nitride (SiNₓ) or silicon oxynitride (SiOₓN_{y}). In other embodiments, a silicon layer (polycrystalline or monocrystalline) may clad one or both sides of starting substrate 210. In still other embodiments, starting substrate 210 may comprise an organic package substrate core, a silicon (e.g., monocrystalline) substrate, or the like.

Starting substrate 210 has a thickness T1 that may vary with implementation. In exemplary embodiments where starting substrate 210 is predominantly a bulk glass preform, thickness T1 is advantageously 500 μm to 1.5 mm to limit warpage while remaining thin enough to permit the formation of through vias at a pitch as small as is enabled by the flatness of the preform.

Returning to FIG. 1, methods 101 continue at block 120 wherein through holes are formed through the starting substrate. The through holes are then metallized to form electrically conductive through vias, which may be referred to as through substrate vias (TSVs) or more particularly through glass vias (TGVs). In the example further illustrated in FIG. 2B, through holes 220 have been formed, for example by laser ablation, an etch process (laser-assisted, or otherwise), or any other technique known to be suitable for the composition and thickness of starting substrate 210. In exemplary embodiments where starting substrate 210 is predominantly a bulk glass preform with a thickness T1 of at least 500 μm, through holes 220 have a minimum (critical) lateral pitch P that is 200 μm, or less, and advantageously 100 μm, or less.

The example illustrated in FIG. 2B is indicative of a symmetrical two-sided hole formation process resulting in through holes 220 that are substantially symmetric about a longitudinal z-axis (demarked in dashed line) but with a laterally tapered (e.g., x dimension) width W that is largest at each of a front-side surface 241 and a back-side surface 242 of starting substrate 210. Through holes 220 have a smallest lateral width W proximal to one-half of thickness T1. The largest width W may vary with implementation. However, in some examples the largest width W is 100 μm, or less, and advantageously 50 μm, or less. As further illustrated in FIG. 2B, in addition to through holes 220, blind holes or recesses 225 may also be fabricated into back-side surface 242. As further described below, blind holes or recesses may be similarly fabricated into front-side surface 241.

FIG. 2C further illustrates metallization of the blind and through holes. In some examples, one or more metals 251 (e.g., copper) are deposited (e.g., plated) upon surfaces of starting substrate 210. Following planarization of starting substrate 210, metals 251 remain as conductive through vias 250 and conductive blind vias 260. In other examples, one or more liner materials 252 may be deposited upon a surface of starting substrate 210 prior to a subsequent deposition of metals 251. Liner materials 252 may be magnetic, for example. Following planarization of starting substrate 210, metals 251 and magnetic liner materials 252 may be retained as through inductor cores 255.

Returning to FIG. 1, one or more passive components may be received at input 125. Introduction of passive components is optional in the practice of methods 101, as emphasized in FIG. 1 through a use of dashed line. Passive components may be electrical components such as resistors, capacitors or inductors, or the like. Passive components received at input 125 may also be optical components, such as optical waveguides, couplers, or the like. Any such passive components are assembled upon the starting substrate, and may be advantageously assembled into recesses formed into the starting substrate at block 130. One or more passive components may be assembled into each recess formed at block 130. Such recesses may be formed according to any technique suitable for the starting substrate. In examples where the starting substrate is predominantly glass, any etch or ablation process suitable for glass may be practiced to form recesses into at least the front-side surface of the starting substrate.

In the example further illustrated in FIG. 2D, a recess 225 has been etched into front-side substrate surface 241. Recess 225 exposes conductive vias 260. As further illustrated in FIG. 2E, a passive component 265 has been assembled into recess 225 so that it is laterally adjacent to a sidewall 221 of starting substrate 210. Passive component 265 is in electrical contact with conductive vias 260. Such electrical contact may be the result of a direct bond between terminals of passive component 265 and vias 260, or through an intervening interconnect metallization, such as a solder feature (not depicted). Passive component 265 may further comprise one or more terminals 266 exposed at front-side substrate surface 241 with a remainder of passive component 265 being substantially embedded within thickness T1 of starting substrate 210. Hence, component 265 is embedded within recess 225 rather than merely attached to a planar front-side or back-side surface. In some examples, a pick- and—place machine positions component 265 within recess 225. Any permanent or temporary adhesive or bond film known to be suitable for die attach (e.g., a thermoset) may be employed to hold component 265 during subsequent processing.

Starting substrate 210 may surround passive component 265, for example forming a perimeter about the edges of one passive component 265. Alternatively, more than one passive component 265 may be located within a single recess 225. As the dimensions of the recess 225 are larger than those of passive component 265, for example to accommodate placement error, a gap between sidewall 221 and passive component 265 may be filled with any suitable filler, such as a dielectric material. The filler may be a mold compound, for example. The filler may also be an organic dielectric material, for example applied wet and cured. Exposed surfaces of the assembly may then be planarized, for example with a grind or polish process suitable for the composition of component 265 die and starting substrate 210.

After the formation of conductive through vias 250 starting substrate 210 may be affixed to a handle or carrier 270, as further depicted in FIG. 2F. Carrier 270 may have any suitable composition and be of any suitable thickness, as embodiments herein are not limited in this context.

Returning to FIG. 1, methods 101 continue at block 140 where an electrical routing structure is built up over at least one side of the starting substrate, thereby forming a primary substrate suitable for assembly with IC die. The electrical routing structure is electrically coupled to the through vias and may, for example, comprise one or more levels of metallization features embedded within any suitable dielectric material. The electrical routing structure formed at block 140 is to interconnect multiple IC die to each other and to couple one or more of the IC to the through vias. Accordingly, the metallization feature pitch of the routing structure is advantageously minimized for highest interconnect density.

In the example illustrated in FIG. 2G, a routing structure 280 has been built-up over front-side surface 241 to arrive at a primary substrate. Routing structure 280 comprises one or more levels of RDL metallization features 282 embedded within one or more layers of dielectric material 281. RDL metallization features 282 may comprise one or more metals, with one example being predominantly copper. At least some of RDL metallization features 282 are to electrically bridge together two or more IC dies, preferably with the finest metallization line:space feature pitch that can be directly patterned (e.g., <3 μm lines and spaces) as limited by the flatness of the starting substrate 210. Routing structure 280 further comprises metallization features 282 that are to interconnect multiple IC dies to conductive through vias 250. In some examples where through vias 250 have a lateral pitch P of no more than 100 μm, routing structure 280 may comprise interconnect interfaces having a 1:1 correspondence with through vias 250. Hence, routing structure 280 may couple power directly from through vias 250 and need not necessarily redistribute such power routes.

Depending on the embodiment, dielectric material 281 may be any of a molding compound, a spin-on material, or dry film laminate material, for example. Dielectric material 281 may be introduced wet/uncured into a cast and then dried/cured. Alternatively, dielectric material 281 may be introduced as a semi-cured dry film that is fully cured following its application to starting substrate 210.

Although the composition of dielectric material 281 may vary with implementation, in some advantageous embodiments dielectric material 281 is an organic dielectric, such as, an epoxy resin, phenolic-glass, or a resinous film such as the GX-series films commercially available from Ajinomoto Fine-Techno Co., Inc.(ABF). Dielectric material 281 may comprise epoxy resins (e.g., an acrylate of novolac such as epoxy phenol novolacs (EPN) or epoxy cresol novolacs (ECN)). In some specific examples, dielectric material 281 is a bisphenol-A epoxy resin, for example including epichlorohydrin. In other examples, dielectric material 281 includes aliphatic epoxy resin.

Returning to FIG. 1, methods 101 continue at block 150 where at least one EIC die and at least one PIC die are assembled to the primary substrate and, more particularly, to the electrical routing structure that was formed at block 140. EIC die assembled at block 150 may each comprise any electrical circuitry, with one example being logic circuitry comprising logic gates. Each PIC die assembled at block 150 may comprise any photonic circuitry suitable for the detection, emission or processing (e.g., filtering, multiplexing and demultiplexing) of optical signals.

In the example illustrated in FIG. 2H, EIC die 291-294 are assembled to interconnect interfaces within a top metallization level of routing structure 280 as the first die of a co-packaged multi-die OEIC device structure 201. EIC die 291-294 may be directly bonded to routing structure 280, or, electrically coupled through intervening electrical interconnects 285, which may comprise solder of any suitable composition. As shown, EIC die 291-294 may have any range of z-thicknesses T2. In the example illustrated, EIC die 291-293 are each flip-chip attached with integrated circuitry within each die being proximal to front-side substrate surface 241. EIC die 294 however comprises through die vias 299 with integrated circuitry being distal from front-side substrate surface 241.

Each of EIC die 291-294 may be a fully functional ASIC, or may be a chiplet or tile that has more limited functionality supplementing the function of one or more other IC dies that are to be part of the same multi-die device. A chiplet or tile may, for example, be any of a wireless radio circuit, microprocessor core, electronic memory circuit, floating point gate array (FPGA), power management and/or power supply circuit, or include a MEMS device. In some examples, one or more of EIC die 291-294 include one or more banks of active repeater circuitry to improve multi-die interconnects (e.g., network-on-chip architectures). In other examples, one or more of EIC die 291-294 includes clock generator circuitry or temperature sensing circuitry. In other examples, one or more of EIC die 291-294 include logic circuitry that, along with other EIC die 291-294 implement multi-chiplet aggregated logic circuitry (e.g., mesh network-on-chip architectures). In some specific examples, at least one of EIC die 291-294 includes microprocessor core circuitry, for example comprising one or more shift registers.

EIC die 291-294 advantageously comprise field effect transistors (FETs) with a device pitch of 80 nm, or less. The FETs may be of any architecture (e.g., planar, non-planar, single-gate, multi-gate, stacked nanosheet, etc.). In some embodiments, FET terminals have a feature pitch of 20-40 nm. Additionally, or in the alternative, EIC die 291-294 may include active devices other than FETs. For example, EIC die 291-294 may include electronic memory structures, such as magnetic tunnel junctions (MTJs), capacitors, or the like.

EIC die 291-294 may comprise one or more IC die metallization levels embedded within an insulator. While the IC die metallization features may have any composition(s) of sufficient electrical conductivity, in exemplary embodiments, the IC die metallization features are predominantly copper (Cu). In other examples, the metallization features are predominantly other than Cu, such as, but not limited to predominantly Ru, or predominantly W. An uppermost one of the metallization features within EIC die 291-294 may have a feature pitch ranging from 100 nm to several microns, for example.

In addition to EIC die, one or more glass preforms comprising an optical waveguide may be assembled upon the primary substrate as an optical interface to one or more PIC dies co-assembled on to the primary substrate. One end of the optical waveguide may be optically coupled to a PIC die while a second end of the optical waveguide may be optically coupled to an optical connector or coupler that is to interface one PIC die to another PIC die and/or to interface PIC die on the primary substrate to a host component. In further reference to methods 101 (FIG. 1), such glass preforms may be assembled at block 150 in conjunction with assembly of EIC die and PIC die. The glass preform may include the optical connector or a discrete optical connector may be separately assembled upon the primary substrate. Alternatively, a PIC die assembled at block 150 may be optically interfaced through a passive optical component comprising an optical waveguide and/or optical connector that was previously assembled with the starting substrate (e.g., assembled within a recess at block 130).

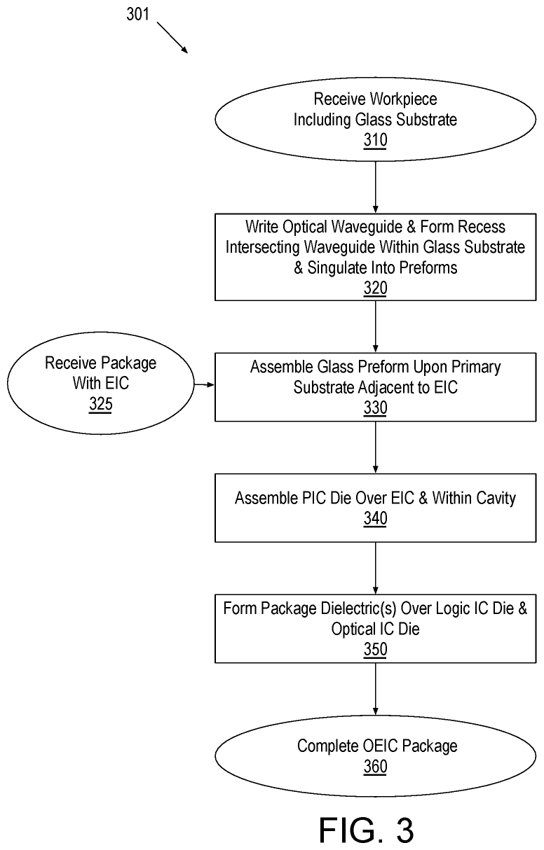

FIG. 3 illustrates a flow diagram of methods 301 for forming and assembling a glass preform suitable for optically interfacing a PIC in a multi-die device structure, in accordance with some exemplary embodiments of methods 101. Methods 301 may therefore be practiced during an implementation of methods 101.

Methods 301 begin at input 310 with the receipt of a workpiece including a glass substrate. The glass substrate may be supported by a carrier or handle substrate, such as any of those known to be suitable for optical device manufacture or microelectronic device manufacture. The glass substrate may again have a flatness comparable to that of a silicon wafer, but of a larger lateral dimension suitable for large format panel processing.

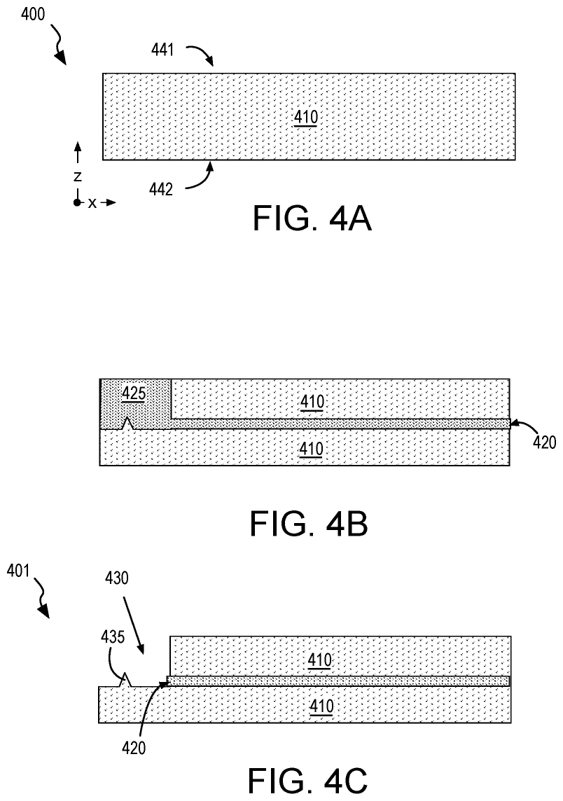

In the example illustrated in FIG. 4A, a workpiece 400 comprises a glass starting substrate 410. Starting substrate 410 is also advantageously predominantly silica (e.g., silicon and oxygen). Any dopants (e.g., boron, phosphorus) may be present in starting substrate 410 (e.g., borosilicate glass, etc.) as embodiments herein are not limited in this respect. Although not depicted, one or more material may clad either or both of the top-side surface 441 or bottom-side surface 442. Exemplary cladding materials include silicon nitride (SiNₓ) or silicon oxynitride (SiOₓN_{y}). In other embodiments, a silicon layer (polycrystalline or monocrystalline) may clad one or both sides of a glass.

Returning to FIG. 3, methods 301 continue at block 320 where one or more optical waveguides are written in the glass. In exemplary embodiments, the waveguide is to intersect a recess within the glass that is to host one or more PIC dies and is dimensioned accordingly. If recesses not also patterned at block 320, the glass preform received at input 310 may instead already include such recesses.

In the example further illustrated in FIG. 4B, a waveguide 420 is written with laser radiation that alters one or more properties of glass starting substrate 410 including the refractive index. In some exemplary embodiments, the laser radiation is pulsed (e.g., at a femtosecond rate), which renders glass exposed more susceptible to etching by certain chemical etchants. The laser patterning process may therefore both define waveguide 420 and define a region 425. As further illustrated in FIG. 4C, a subsequent etch process forms a recess or cavity 430 intersecting a first end of waveguide 420. In some advantageous embodiments, the process(es) defining waveguide 420 and/or cavity 430 also define a physical alignment feature 435 that will guide assembly of a PIC.

Following definition of the optical waveguide(s), workpiece 400 may be singulated into a plurality of glass preforms 401, each glass preform 401 including at least one optical waveguide 420. Optionally, prior to singulation, an optical connector or coupler (not depicted) may be assembled in proximity to an end of the waveguide(s) opposite cavity 430. Such an optical coupler may comprise one or more mirror facets and/or lenses, for example.

Returning to FIG. 3, methods 301 continue with the receipt of a package comprising an EIC die at input 325. In exemplary embodiments, the package received at input 325 is the primary substrate introduced above in the context of methods 101 (FIG. 1) following attachment of at least one EIC die. At block 330, one or more of the glass preforms prepared at block 320 are assembled upon the primary substrate. Assembly of the glass preform may include aligning a cavity within the preform to be in proximity to an EIC die that is operable to interface with a PIC die, which is to be optically coupled with the waveguide(s) embedded within the glass preform.

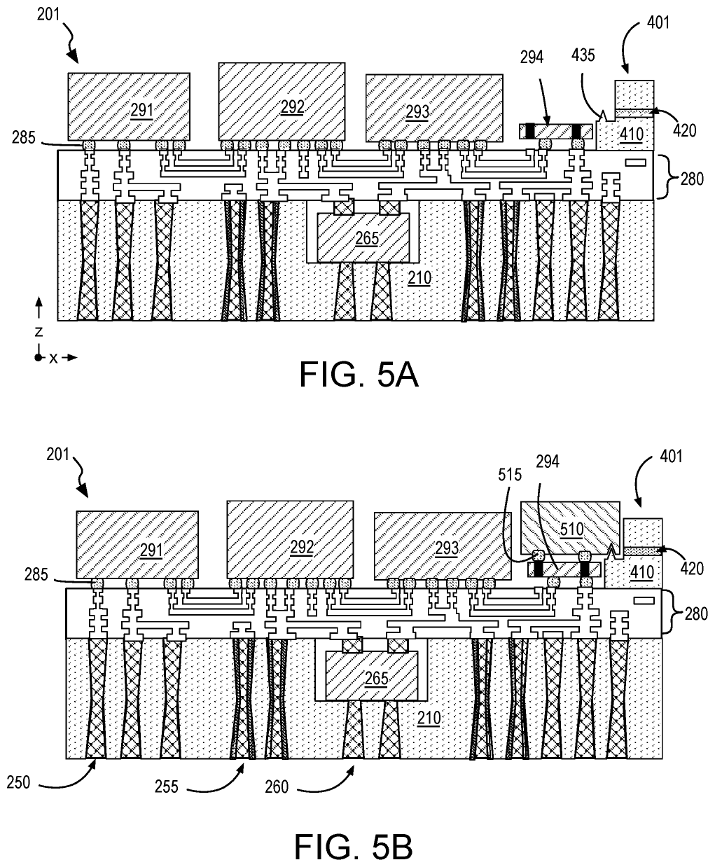

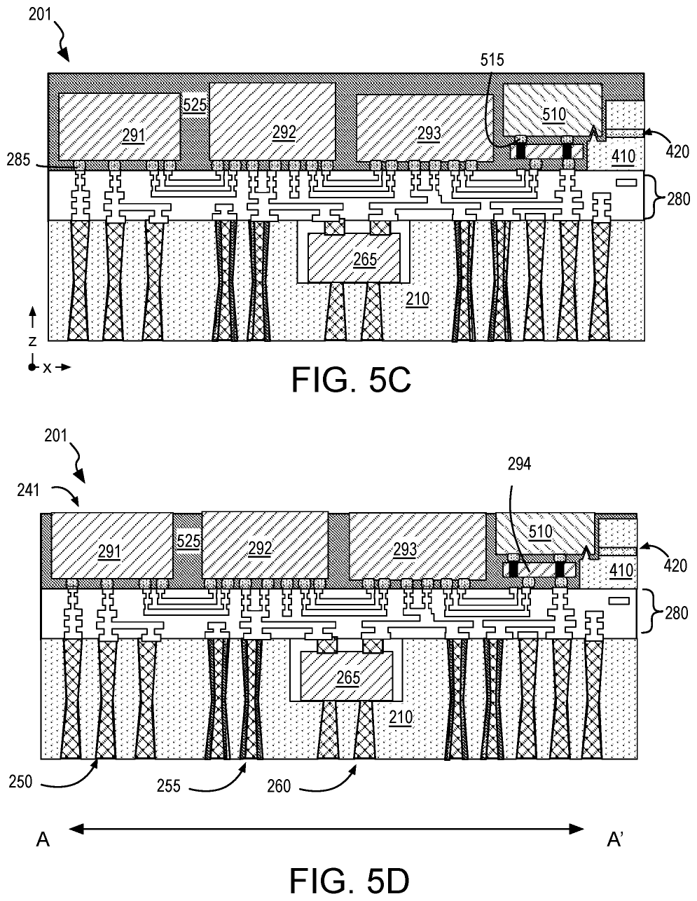

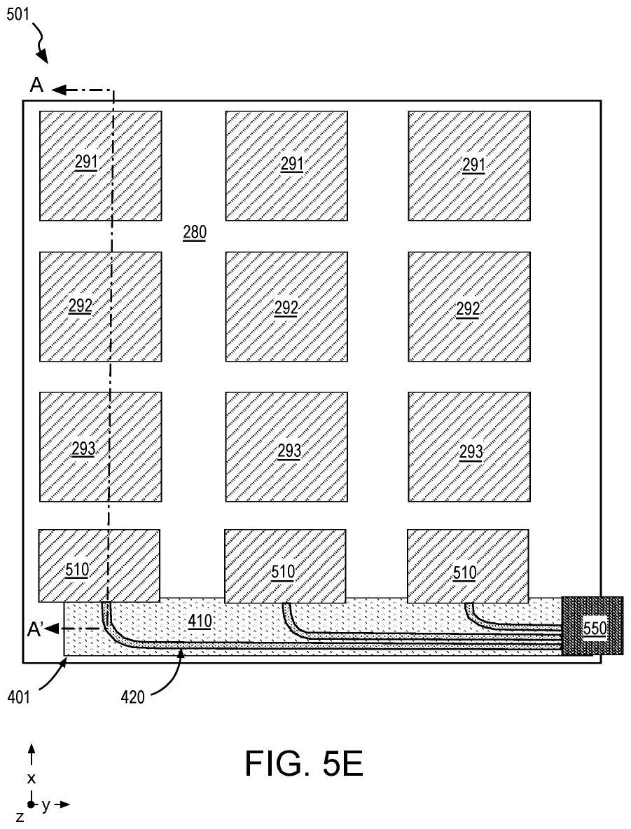

FIG. 5A illustrates an example where glass preform 401 has been assembled upon co-packaged multi-die OEIC device structure 201. Glass preform 401 may be adhered to a top surface of electrical routing structure 280, for example with any suitable bond film (not depicted). As shown, cavity 430 is laterally adjacent to an edge of EIC die 294.

Returning to FIG. 3, methods 301 continue at block 340, where a PIC die is assembled with the glass preform and primary substrate to complete co-packaging of EIC and PIC dies. In advantageous embodiments, the PIC die is physically aligned within a recess in the glass preform so that the PIC die is efficiently coupled to an end of the optical waveguide(s) within the preform. The PIC die and EIC die are therefore electrically coupled to the electrical routing structure of the primary substrate and the PIC die is optically coupled to the glass preform, for example through an amount of free space propagation controlled by placement of the PIC die.

FIG. 5B further illustrates an example where a PIC die 510 has been assembled over EIC die 294 and in close proximity to optical waveguide 420, for example as determined by alignment feature 435. PIC die 510 may have any photonic and/or electro-optical die architecture. In some examples, PIC die 510 comprises a photodetector and/or photoemitter (e.g., diode or laser). In other examples, PIC die 510 comprises an optical multiplexer and/or optical demultiplexer. PIC die 510 may be predominantly silicon or comprise other semiconductor materials advantageous for optical devices such as, but not limited to, germanium, SiₓGe₁₋ₓ, GeₓSn₁₋ₓ, GaAs, InGaAs, or InP. In the illustrated example, PIC die 510 is electrically coupled to EIC die 294 through interconnects 515, which may comprise any solder, for example. PIC die 510 is therefore stacked upon EI die 294 and overlaps some portion of glass perform 401.

Returning to FIG. 3, methods 301 continue at block 350 where one or more package dielectric materials are formed over any and/or all of the EIC die and PIC die assembled to the primary substrate. A planarization process may then be practiced exposing and/or planarizing top surfaces of the EIC and PIC die with the surrounding dielectric material. The co-packaged opto-electronic IC (OEIC) multi-die device is then completed at block 360, for example according to any known techniques.

FIG. 5C illustrates one example where a package dielectric material 525 has been applied to co-packaged multi-die OEIC device structure 201, covering each of EIC die 291-294 as well as PIC die 510 and preform 401. Package dielectric material 525 may have any composition and may be applied to workpiece 200 according to any technique suitable for the material. Package dielectric material 525 is advantageously an electrical insulator. In some examples, package dielectric material 525 is an organic dielectric, for example comprising an epoxy or polyimide. The organic dielectric may be applied, for example, with a molding process. In other embodiments, package dielectric material 525 is an inorganic dielectric material and may have composition known to be suitable as an insulator of monolithic integrated circuitry, such as, but not limited to, silicon dioxide, silicon nitride, silicon oxynitride, or a low-k material having a relative permittivity below 3.5. Inorganic dielectric materials may be deposited with any techniques known to be suitable, such as, but not limited to chemical vapor deposition (CVD).

FIG. 5D further illustrates co-packaged multi-die OEIC device structure 201 following planarization of package dielectric material 525 with a backside of each of EIC die 291-293 and PIC die 510. A primary substrate comprising many co-packaged multi-die OEIC device structures 201 is now substantially ready to be singulated into a plurality of multi-die device structures or complexes. Each co-packaged device structure is to include electrically interconnected EIC die and PIC die, as well as a primary optical waveguide coupled to the PIC die. The multi-die complex is interconnected by an electrical routing structure that is advantageously on a first piece of bulk glass, and the primary optical waveguide is advantageously embedded within a second piece of bulk glass that is assembled over the electrical routing structure.

FIG. 5E is a plan view of one multi-die co-package OEIC device structure 501, in accordance with some embodiments. In FIG. 5E, the dot-dash A-A′ line denotes the cross-sectional view shown in FIG. 5D. In this example, multi-die device structure 501 includes an 2D (e.g., x-y dimensions) array of EIC dies over routing structure 280. The 2D array comprises a 1D (e.g., y-dimension) array of EIC dies 291 adjacent to 1D arrays of EIC dies 292 and 293. Edges of PIC dies 510 in an adjacent 1D array overlap with a single glass preform 401, which extends a length of the 1D array of PIC dies 510. A second end of optical waveguide 420 intersects an optical end coupler 550 proximal to an edge of multi-die device structure 501. Hence, glass preform 401 may comprise one or more optical waveguides that interface multiple PIC dies 510 and terminate at one or more optical end coupler 550.

Completing discussion of FIG. 1, methods 101 end at output 160 where a co-packaged multi-die opto-electronic IC (OEIC) device structure is assembled upon a host component, such as a secondary substrate as further described below, or any package interposer or circuit board with a suitable electrical and optical interface.

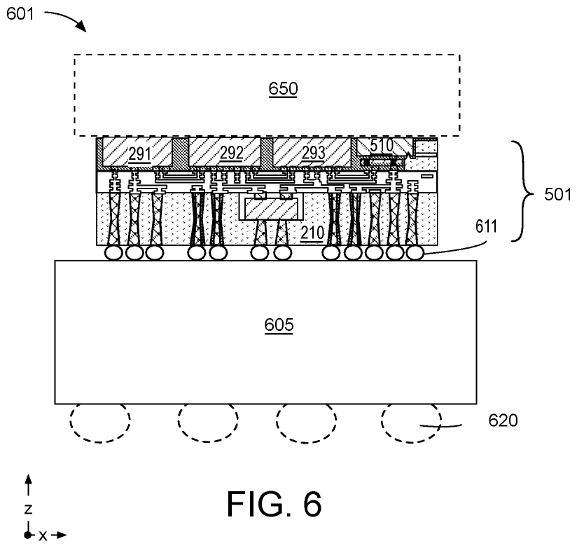

FIG. 6 illustrates an exemplary system 601 including one co-packaged multi-die OEIC device structure 501 attached to a host component 605 with first level interconnects (FLI) 611, in accordance with some embodiments. In exemplary embodiments, FLI 611 are solder (e.g., SAC) microbumps although other interconnect features are also possible. In some embodiments, host component 605 is predominantly silicon. Host component 605 may also comprise one or more alternative materials known to be suitable as interposers or package substrates (e.g., an epoxy preform, cored or coreless laminate board, etc.). Host component 605 may include one or more metallized redistribution levels (not depicted) embedded within a dielectric material. Host component 605 may also include one or more IC die embedded therein.

Host component 605 may include second level interconnects (SLI) 620 illustrated in dashed line. SLI 620 may comprise any solder (ball, bump, etc.) suitable for a given host board architecture (e.g., surface mount FR4, etc.). Also illustrated in dashed line, one or more heat spreaders and/or heat sinks 650 may be further coupled to multi-die device structure 501, which may be advantageous, for example, where EIC dies 291-293 comprise one or more CPU cores or other circuitry of similar power density.

In some embodiments, host component 605 comprises a secondary substrate that advantageously further comprises another bulk slab of glass. The secondary substrate may optically and electrically interconnect an aggregation of multi-die EIC and OIC device structures, such as those described above. Like the multi-die package device earlier described, secondary substrates may be fabricated at a panel level for high volume manufacturing. The secondary substrates may also be electrically tested prior to further assembly with “known-good” co-packaged multi-die OEIC device structures.

In the aggregate, co-packaged multi-die OEIC device structures in accordance with some embodiments communicate with one another via a co-packaged optical interface. Individual ones of the co-packaged multi-die OEIC device structures assembled upon the secondary substrate may be electrically interconnected through an electrical routing structure built-up upon a side of the secondary substrate (e.g., like as described above for a primary substrate). Power routing to aggregated co-packaged multi-die OEIC device structures may similarly pass through the secondary substrate by way of conductive through substrate vias.

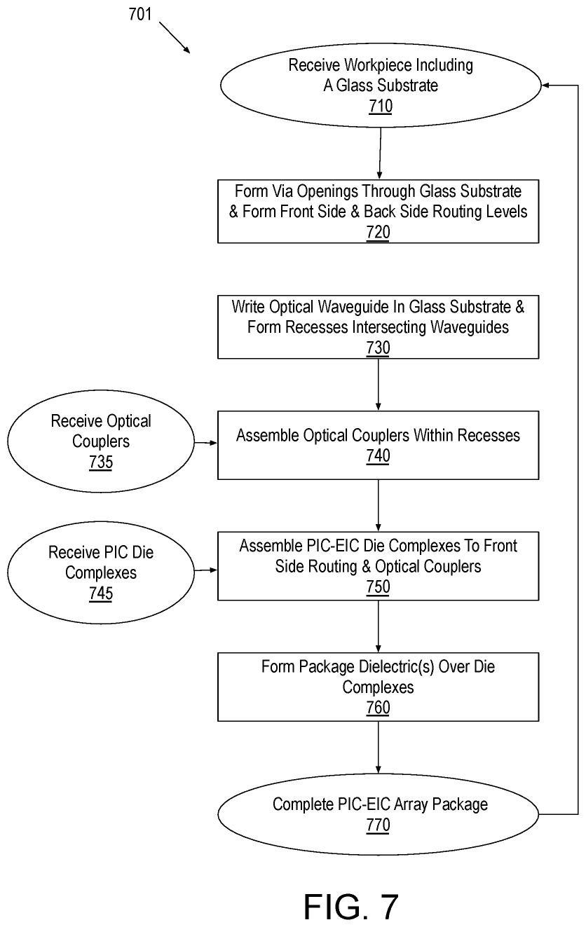

FIG. 7 illustrates a flow diagram of methods 701 for optically and electrically coupling a plurality of the co-packaged multi-die OEIC device structures 501 to a secondary substrate comprising a glass, in accordance with some embodiments. Methods 701 begin at input 710 where a workpiece including a glass starting substrate is received.

The glass starting substrate may be supported by a carrier or handle substrate, such as any of those known to be suitable for optical device manufacture or microelectronic device manufacture. The glass starting substrate may again have a flatness comparable to that of silicon wafers, but a larger lateral dimension suitable for large format panel processing.

Methods 701 continue at block 720 wherein through holes are formed through the starting substrate. The though holes are metallized to form electrically conductive through vias and an electrical routing structure is built up over at least one side, and advantageously both sides of the starting substrate, thereby forming a secondary substrate suitable for assembly with a primary substrate described elsewhere herein. The electrical routing structures are electrically coupled to the through vias and may, for example, comprise one or more levels of metallization features embedded within any suitable dielectric material formed over a surface of the starting substrate. The electrical routing structure formed at block 720 is to interconnect multiple co-packaged multi-die OEIC device structures to each other. Accordingly, the feature pitch of a top level of metallization in one of the routing structures formed at block 720 is advantageously compatible with the pitch of the through vias in a primary substrate.

Methods 701 continue at block 730 where one or more secondary optical waveguides are written in the glass of the secondary substrate. The secondary optical waveguide(s) is(are) to interface with an optical coupler of the co-packaged multi-die OEIC device structures to be assembled upon the secondary substrate. In exemplary embodiments, each secondary waveguide is to intersect a recess formed in the glass of the secondary substrate. The recess may be dimensioned as needed to host a vertical optical coupler. In some embodiments, the secondary optical waveguide(s) and recess(es) may be defined within the secondary substrate in substantially the same manner as described above for defining a primary waveguide.

An optical coupler received at input 735 may comprise any passive or active optics suitable for coupling a secondary waveguide to a primary waveguide. At block 740, the optical coupler received at input 735 is assembled into a recess intersecting a secondary waveguide. In some exemplary embodiments, the optical coupler received at input 735 is a vertical coupler comprising one or more mirror facet or lens suitable for directing lights between a horizontal plane of a secondary waveguide and an overlying optical coupler of a primary substrate.

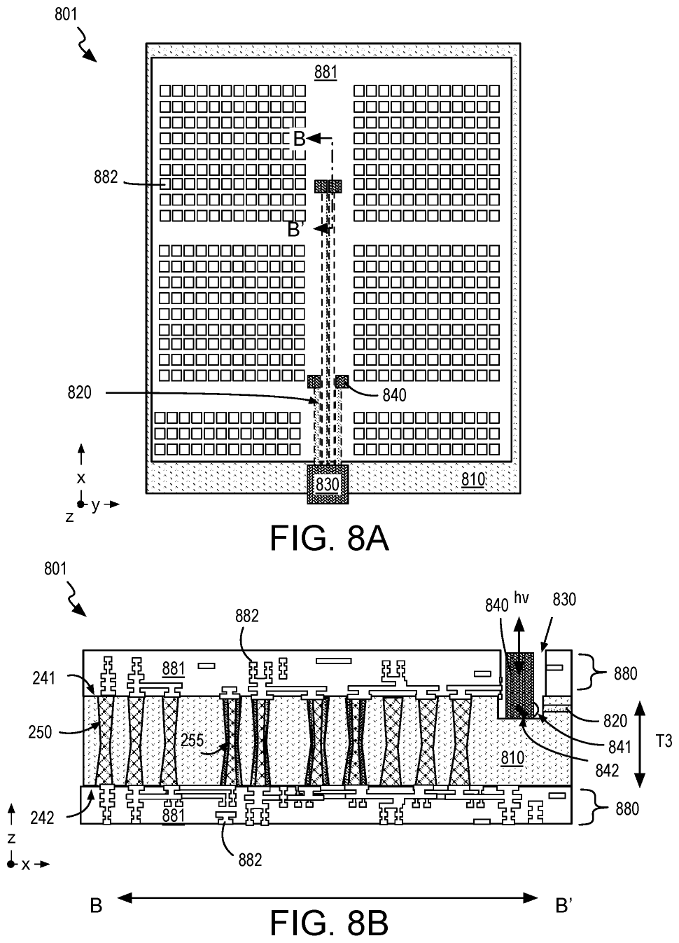

FIG. 8A illustrates a plan view of a portion of a secondary substrate 801, in accordance with some embodiments. Although not depicted, a monolithic workpiece may comprise a plurality of the units illustrated in FIG. 8A. FIG. 8B illustrates a cross-sectional view of a portion of secondary substrate 801 along the dashed B-B′ line illustrated in FIG. 8A, in accordance with some embodiments.

In the example illustrated in FIG. 8A, a glass starting substrate 810 is advantageously predominantly silica (e.g., silicon and oxygen). Any dopants (e.g., boron, phosphorus) may be present in glass starting substrate 810 as embodiments herein are not limited in this respect.

A routing structure 880 (FIG. 8B) comprising metallization features 882 embedded in package dielectric material 881 have been built-up over a front-side surface 241. Another routing structure 880 has been similarly built-up over back-side surface 242. The two routing structures 880 are electrically coupled to each other by through vias 250 extending through thickness T3 of substrate 810. Although thickness T3 may vary with the desired pitch of through vias 250, in some examples thickness T3 is significantly greater than thickness T1 (FIG. 2A) and may be more than 500 μm. Package dielectric material 881 may have any composition, such as one or more of those described for package dielectric material 281 (e.g., FIG. 2G).

As further illustrated in FIG. 8A, a top level of metallization features 882 may comprise a plurality of interconnect interfaces through which a primary substrate may be electrically coupled. Routing structure 880 may distribute a second terminus of each electrical route either to another of the metallization features 882 or to a through via 250. As shown in FIG. 8B, a top level of metallization features 882 within routing structure 880 on back-side surface 242 may comprise another plurality of interconnect interfaces through which secondary substrate 801 may be electrical coupled to a host component (not depicted).

Secondary substrate 801 further comprises a plurality of secondary optical waveguides 820 embedded within glass substrate 810. Secondary waveguides 820 may be written with laser radiation that alters one or more properties of glass substrate 810 including the refractive index, for example substantially as described above for a primary optical waveguide. A waveguide patterning process may also define a region that is etched to form a recess 830 intersecting a first end of waveguide 820.

A vertical optical connector or coupler 840 is assembled within recess 830 in proximity to a first end of the secondary optical waveguide 820. In the illustrated examples, vertical optical coupler 840 comprises one or more lenses 841 and/or mirror facets 842 and is suitable for coupling light to/from waveguide 820 (e.g., x-dimensional direction of propagation) into a vertical (z-dimensional direction of propagation). As shown in FIG. 8A, each waveguide 820 terminates at one vertical optical coupler 840 while a second end of each waveguide 820 is optically coupled with another vertical optical coupler 840 that is to couple light to/from each waveguide 820 to a host component at a next-higher level of system integration.

With the secondary substrate ready for assembly, methods 701 (FIG. 7) continue at block 750 where co-packaged PIC-EIC multi-die structures (complexes) are assembled to electrical and optical routing structures on a front-side surface of a secondary substrate. Such assembly may be with interconnect features comprising solder, or through a direct bonding between metallization features of primary and secondary substrates. Following die assembly, one or more package dielectric materials may be formed over and between individual co-packaged multi-die OEIC device structures at block 760. Methods 701 end at output 770 where any known techniques may be practiced to complete an aggregated co-packaged multi-die OEIC device structure. Methods 701 may be practiced again (i.e., iterated) for a next level of integration. For example, the aggregated packaged PIC-EIC complex generated at output 770 may be received at input 745 during a second iteration of methods 701 and further assembled with a tertiary substrate comprising glass that has been similarly built-up to again include both an electrical routing structure and an optical routing structure.

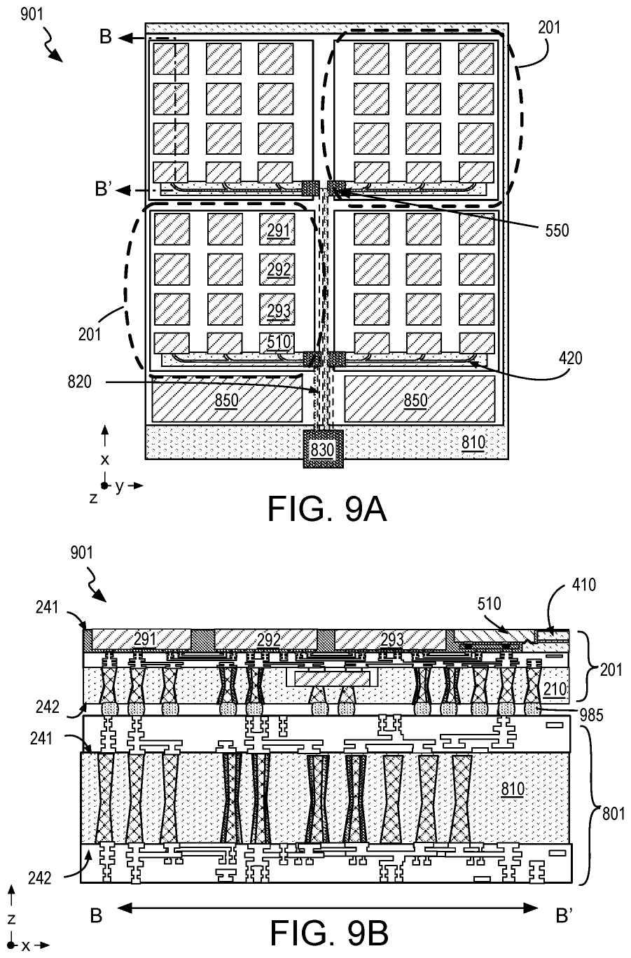

FIG. 9A illustrates a plan view of an aggregated PIC-EIC die complex 901 comprising of a plurality of PIC-EIC multi-die device structures 201 attached to secondary substrate 801, in accordance with some embodiments. As shown, an optical end coupler 550 of each co-packaged multi-die OEIC device structure 201 is assembled to couple with optical coupler 840 (as shown in FIG. 8A-8B). Hence each PIC 510 of each co-packaged multi-die OEIC device structure 201 is optically coupled to a secondary optical waveguide 820. Any number of other packaged devices and/or IC die packages may be similarly assembled to secondary substrate 801. For example, in FIG. 9A memory IC devices 850 are interconnected to co-packaged multi-die OEIC device structures 201, for example through electrical routing structure 880 (FIG. 8B).

FIG. 9B illustrates a cross-sectional view of aggregated PIC-EIC die complex 901 along the B-B′ line illustrated in FIG. 9A. As shown in FIG. 9B, interconnect features 985 electrically couple each co-packaged multi-die OEIC device structure 201 to secondary substrate 801 in a front-side to back-side configuration. Interconnect features 985 may comprise any suitable solder feature, for example. Aggregated PIC-EIC die complex 901 may therefore include at least three pieces of bulk glass (substrates 210, 410 and 810).

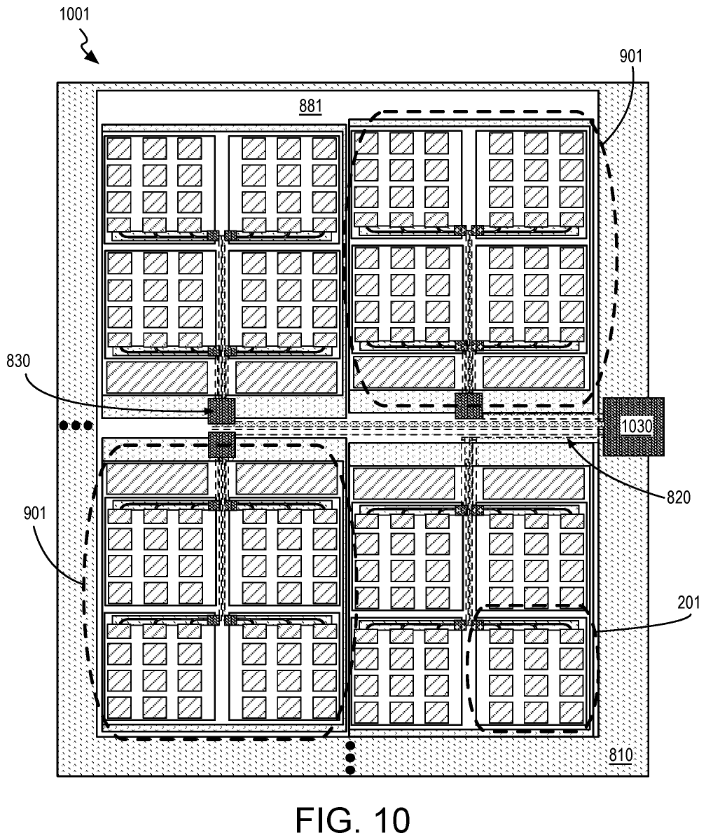

Aggregated PIC-EIC die complexes may be replicated over any desired surface area of the secondary substrate, with each additional complex being able to electrically tested “known-good” prior to assembly. FIG. 10, for example, illustrates a plan view of a two-dimensional (2D) arrayed device 1001 including a plurality of aggregated complexes 901 assembled over an area of secondary substrate 810. In the illustrated embodiment, there are 16 units of co-packaged multi-die OEIC device structures 201. Each of the four aggregated complexes 901 may be electrically coupled through an electrical routing structure of secondary substrate 801. Each aggregated complex 901 may be coupled optically through an individual vertical optical coupler 840. Alternatively, secondary optical waveguide 820 may extend beyond each aggregated complex 901 so that a plurality of aggregated complexes is optically coupled to a single optical coupler 1030 responsible for optically interfacing the entire population of aggregated complexes 901 assembled to secondary substrate 801.

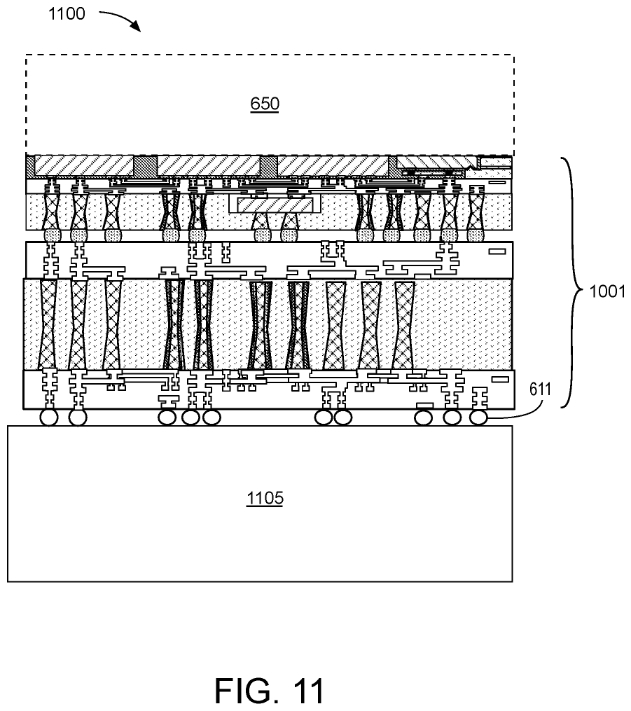

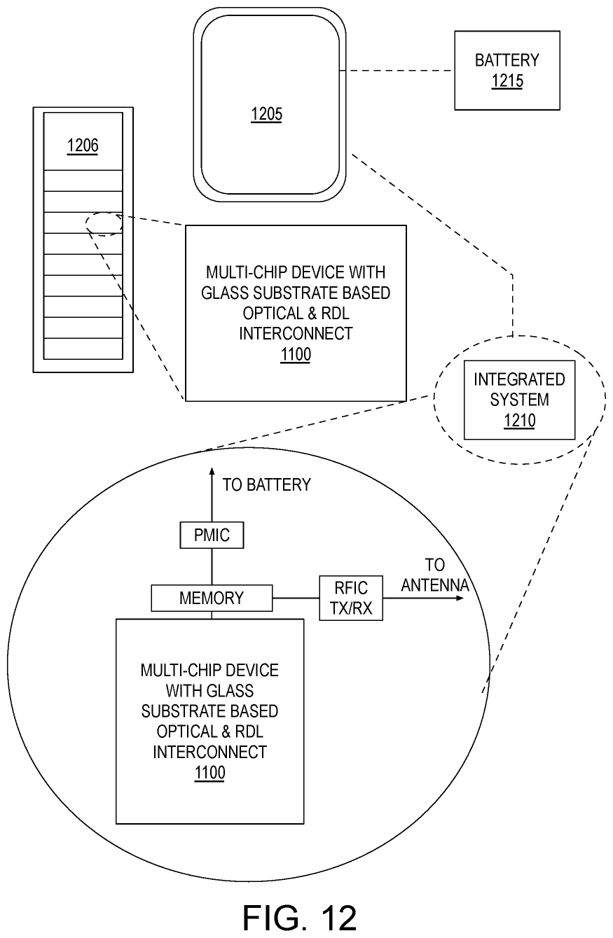

FIG. 11 illustrates an exemplary system including one multi-die device structure 1100 attached to host component 1105 with interconnects 611, in accordance with some embodiments. In exemplary embodiments, interconnects 611 comprise solder (e.g., SAC) microbumps although other interconnect features are also possible. In some embodiments, host component 1105 is predominantly silicon. Host component 1105 may also comprise one or more alternative materials known to be suitable as interposers or package substrates (e.g., an epoxy preform, cored or coreless laminate board, etc.). Host component 1105 may include one or more metallized redistribution levels (not depicted) embedded within a dielectric material. Host component 1105 may also include a printed circuit board (PCB). Also illustrated in dashed line, one or more heat spreaders and/or heat sinks 650 may be further coupled to array structure 1001.

FIG. 12 illustrates a mobile computing platform 1205 and a data server machine 1206 employing a multi-die IC device with PIC and EIC complexes assemble in a glass substrate and interconnected with redistribution layer metallization features and optical waveguides, for example as described elsewhere herein. Server machine 1206 may be any commercial server, for example including any number of high-performance computing platforms disposed within a rack and networked together for electronic data processing, which in the exemplary embodiment includes multichip device 1100, for example as described elsewhere herein. The mobile computing platform 1205 may be any portable device configured for each of electronic data display, electronic data processing, wireless electronic data transmission, or the like. For example, the mobile computing platform 1205 may be any of a tablet, a smart phone, laptop computer, etc., and may include a display screen (e.g., a capacitive, inductive, resistive, or optical touchscreen), an integrated system 1210, and a battery 1215.

As illustrated in the expanded view, multi-die device 1100 is coupled to one or more of a power management integrated circuit (PMIC) or RF (wireless) integrated circuit (RFIC) including a wideband RF (wireless) transmitter and/or receiver. A PMIC may perform battery power regulation, DC-to-DC conversion, etc., and so has an input coupled to battery 1215 and with an output providing a current supply to other functional modules. As further illustrated, in the exemplary embodiment, an RFIC has an output coupled to an antenna (not shown) to implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, and beyond.

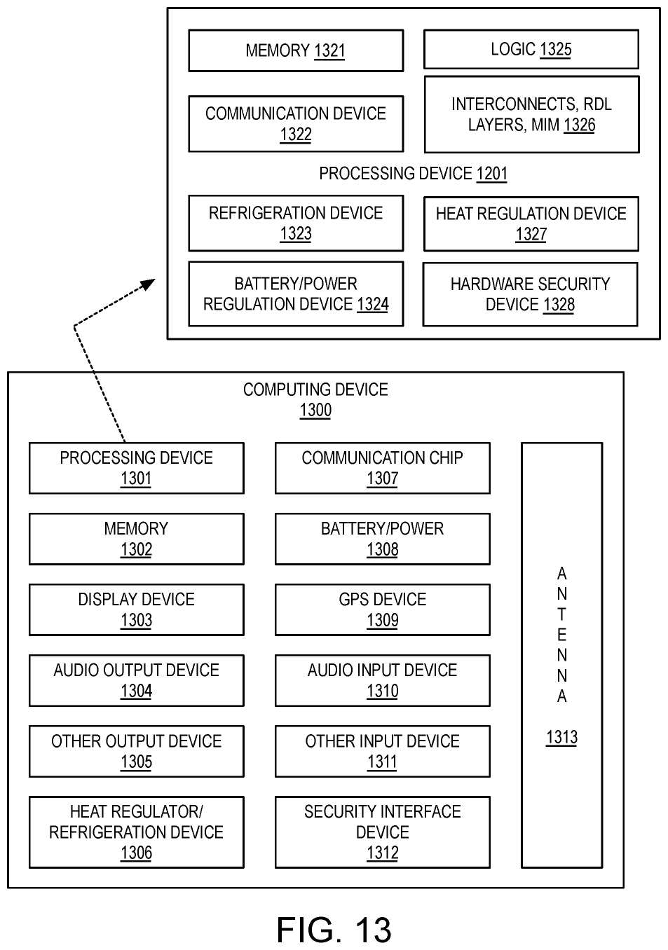

FIG. 13 is a block diagram of a cryogenically cooled computing device 1300 in accordance with some embodiments. For example, one or more components of computing device 1300 may include any of the devices or structures discussed elsewhere herein. A number of components are illustrated in FIG. 13 as included in computing device 1300, but any one or more of these components may be omitted or duplicated, as suitable for the application. In some embodiments, some or all of the components included in computing device 1300 may be attached to one or more printed circuit boards (e.g., a motherboard). In some embodiments, various ones of these components may be fabricated onto a single system-on-a-chip (SoC) die. Additionally, in various embodiments, computing device 1300 may not include one or more of the components illustrated in FIG. 13, but computing device 1300 may include interface circuitry for coupling to the one or more components. For example, computing device 1300 may not include a display device 1303, but may include display device interface circuitry (e.g., a connector and driver circuitry) to which display device 1303 may be coupled.

Computing device 1300 may include a processing device 1301 (e.g., one or more processing devices). As used herein, the term processing device or processor indicates a device that processes electronic data from registers and/or memory to transform that electronic data into other electronic data that may be stored in registers and/or memory. Processing device 1301 may include a memory 1321, a communication device 1322, a refrigeration/active cooling device 1323, a battery/power regulation device 1324, logic 1325, interconnects 1326, a heat regulation device 1327, and a hardware security device 1328.

Processing device 1301 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices.

Processing device 1301 may include a memory 1302, which may itself include one or more memory devices such as volatile memory (e.g., dynamic random-access memory (DRAM)), nonvolatile memory (e.g., read-only memory (ROM)), flash memory, solid state memory, and/or a hard drive. In some embodiments, memory 1321 includes memory that shares a die with processing device 1301. This memory may be used as cache memory and may include embedded dynamic random-access memory (eDRAM) or spin transfer torque magnetic random-access memory (STT-M RAM).

Computing device 1300 may include a heat regulation/refrigeration device 1306. Heat regulation/refrigeration device 1306 may maintain processing device 1301 (and/or other components of computing device 1300) at a predetermined low temperature during operation. This predetermined low temperature may be any temperature discussed elsewhere herein.

In some embodiments, computing device 1300 may include a communication chip 1307 (e.g., one or more communication chips). For example, the communication chip 1307 may be configured for managing wireless communications for the transfer of data to and from computing device 1300. The term “wireless” and its derivatives may be used to describe circuits, devices, systems, methods, techniques, communications channels, etc., that may communicate data through the use of modulated electromagnetic radiation through a nonsolid medium.

Communication chip 1307 may implement any wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards.

Communication chip 1007 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. Communication chip 1007 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). Communication chip 1307 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. Communication chip 1307 may operate in accordance with other wireless protocols in other embodiments. Computing device 1300 may include an antenna 1313 to facilitate wireless communications and/or to receive other wireless communications (such as AM or FM radio transmissions).

In some embodiments, communication chip 1307 may manage wired communications, such as electrical, optical, or any other suitable communication protocols (e.g., the Ethernet). As noted above, communication chip 1307 may include multiple communication chips. For instance, a first communication chip 1307 may be dedicated to shorter-range wireless communications such as Wi-Fi or Bluetooth, and a second communication chip 1307 may be dedicated to longer-range wireless communications such as GPS, EDGE, GPRS, CDMA, WiMAX, LTE, EV-DO, or others. In some embodiments, a first communication chip 1307 may be dedicated to wireless communications, and a second communication chip 1307 may be dedicated to wired communications.

Computing device 1300 may include battery/power circuitry 1308. Battery/power circuitry 1308 may include one or more energy storage devices (e.g., batteries or capacitors) and/or circuitry for coupling components of computing device 1300 to an energy source separate from computing device 1300 (e.g., AC line power).

Computing device 1300 may include a display device 1303 (or corresponding interface circuitry, as discussed above). Display device 1303 may include any visual indicators, such as a heads-up display, a computer monitor, a projector, a touchscreen display, a liquid crystal display (LCD), a light-emitting diode display, or a flat panel display, for example.

Computing device 1300 may include an audio output device 1304 (or corresponding interface circuitry, as discussed above). Audio output device 1304 may include any device that generates an audible indicator, such as speakers, headsets, or earbuds, for example.

Computing device 1300 may include an audio input device 1310 (or corresponding interface circuitry, as discussed above). Audio input device 1310 may include any device that generates a signal representative of a sound, such as microphones, microphone arrays, or digital instruments (e.g., instruments having a musical instrument digital interface (MIDI) output).

Computing device 1300 may include a global positioning system (GPS) device 1309 (or corresponding interface circuitry, as discussed above). GPS device 1309 may be in communication with a satellite-based system and may receive a location of computing device 1300, as known in the art.

Computing device 1300 may include another output device 1305 (or corresponding interface circuitry, as discussed above). Examples include an audio codec, a video codec, a printer, a wired or wireless transmitter for providing information to other devices, or an additional storage device.

Computing device 1300 may include another input device 1311 (or corresponding interface circuitry, as discussed above). Examples may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

Computing device 1300 may include a security interface device 1312. Security interface device 1312 may include any device that provides security measures for computing device 1300 such as intrusion detection, biometric validation, security encode or decode, managing access lists, malware detection, or spyware detection.

Computing device 1300, or a subset of its components, may have any appropriate form factor, such as a hand-held or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure.

It will be recognized that the disclosure is not limited to the embodiments so described but can be practiced with modification and alteration without departing from the scope of the appended claims. For example, the above embodiments may include specific combinations of features as further provided below.

In first examples, an integrated circuit (IC) device comprises a routing structure on a first side of a substrate, the routing structure comprising metallization features. The IC device comprises a plurality of electronic IC (EIC) die over the first side of the substrate and electrically interconnected to each other by the routing structure. The IC device comprises photonic IC (PIC) die over the first side of the substrate, the PIC die optically coupled to a first end of an optical waveguide. The IC device comprises a plurality of through vias extending through the substrate from the routing structure to a second side of the substrate, the routing structure electrically coupling the through vias to at least one of the plurality of EIC die.

In second examples, for any of the first examples a glass preform affixed to the first side of the substrate comprises the optical waveguide. A first of the plurality of EIC die attached to the first side of the substrate is adjacent to the glass preform, and the PIC die is attached to the first of the plurality of EIC die, and is in alignment with an end coupler of the optical waveguide

In third examples, for any of the second examples the PIC die is one of a plurality of PIC die arrayed along a first dimension of the routing structure and coupled to an optical waveguide embedded within the glass preform. Each of the plurality of PIC die is adjacent to one of a plurality EIC die arrayed along a second dimension of the first routing structure.

In fourth examples, for any of the second examples the IC device comprises first solder features between the PIC die and the second EIC die.

In fifth examples, for any of the fourth examples the IC device further comprises second solder features between metallization features of the routing structure and each of the first EIC die and the second EIC die.

In sixth examples, for any of the first through fifth examples the substrate comprises glass, the through vias extend through a thickness of the glass, the metallization features are embedded within an organic dielectric material, and the EIC die is coupled to the routing structure either through a direct bond or through solder features.

In seventh examples, for any of the first through sixth examples the first side of the substrate comprises a recess. A passive device is within the recess, between the routing structure and the second side of the substrate, and the passive device is electrically coupled to the routing structure.

In eighth examples, for any of the seventh examples the passive device comprises a coupling capacitor with one or more terminals coupled to the routing structure and one or more terminals coupled to the second side of the substrate by one or more of the through vias.

In ninth examples, for any of the first through eighth examples the substrate is a first substrate and the IC device further comprises a second substrate coupled to the second side of the first substrate. The second substrate comprises glass and a second optical waveguide embedded within the glass. The IC device comprises a second routing structure on a first side of the second substrate, the second routing structure comprising metallization features electrically interconnected to a second end of the through vias and to a first end of a plurality of second through vias extending through the second substrate to a second side of the second substrate. The IC device comprises a vertical optical coupler embedded within a recess in the first side of the second substrate, the vertical optical coupler optically coupling a first end of the second optical waveguide to a second end of the first optical waveguide.

In tenth examples, for any of the ninth examples the first substrate is one of a plurality of first substrates coupled to the second routing structure. The vertical optical coupler is one of a plurality of vertical optical couplers, each of the vertical optical couplers embedded within one of a plurality of recesses in the first side of the second substrate. Each of the plurality of first substrates comprises PIC die and an EIC die, and each PIC die is coupled to a corresponding one of the plurality of vertical optical coupler. A second end of the second optical waveguide is coupled to an optical connector affixed to the second substrate.

In eleventh examples, for any of the ninth through tenth examples the IC device comprises a memory IC die attached to at least one of the first routing structure, or the second routing structure.

In thirteenth examples, an integrated circuit (IC) device comprises a first substrate comprising glass and an optical waveguide embedded within the glass. The IC device comprises a first routing structure on a first side of the first substrate, the first routing structure comprising metallization features electrically interconnected to a first plurality of conductive through vias extending through the first substrate to a second side of the first substrate. The IC device comprises a second substrate coupled to the first routing structure, the second substrate comprising a second plurality of conductive through vias extending through the second substrate. The second substrate further comprises a second routing structure on a side of the second substrate opposite the first routing structure, the second routing structure coupled to the first routing structure through the second through vias. The IC device further comprises an electronic IC (EIC) die electrically coupled to the second routing structure. The IC device further comprises a photonic IC (PIC) die coupled to the optical waveguide through a vertical optical coupler embedded within a recess in the first side of the first substrate.

In fourteenth examples, for any of the thirteenth examples a glass preform is affixed to the second substrate comprises a second optical waveguide coupling the vertical coupler to the PIC die. The EIC die is a first EIC die, and a second EIC die attached to the second substrate is between the first EIC die and the glass preform. The PIC die is attached to the second EIC die, in alignment with an end coupler of the second optical waveguide.

In fifteenth examples, for any of the fourteenth examples the second substrate comprises glass, the first and second routing structures comprise metallization features embedded within an organic dielectric material, and the first and second EIC die are coupled to the second routing structure either through a direct bond or through solder features.

In sixteenth examples, for any of the fourteenth through fifteenth examples the PIC die is one of a plurality of PIC die arrayed along a first dimension of the second routing structure and coupled to an optical waveguide embedded within the glass preform, and each of the plurality of PIC die is adjacent to one of a plurality EIC die arrayed along a second dimension of the second routing structure.

In seventeenth examples, for any of the fourteenth through sixteenth examples the IC device comprises first solder features between the first routing structure and the second through vias, second solder features between the second routing structure and each of the first EIC die and the second EIC die, and third solder features between the PIC die and the second EIC die.

In eighteenth examples, a method comprises receiving a workpiece comprising glass substrate, forming through holes in the glass substrate and forming conductive through vias by metallizing the through holes, building up a routing structure coupled to the through vias; and attaching a glass preform comprising an optical waveguide to a first region of the routing structure. The method comprises attaching a photonic IC (PIC) die over a second region of the routing structure, adjacent to the glass preform, and attaching an electronic integrated circuit (EIC) die over a third region of the routing structure, adjacent to the PIC die.

In nineteenth examples, for any of the eighteenth examples the method comprises attaching a vertical optical coupler to a second glass substrate, the second glass substrate comprising a second optical waveguide and a second routing structure, and attaching the through vias to the second routing structure with the optical waveguide optically coupled to the vertical optical coupler.

In twentieth examples, for any of the eighteenth through nineteenth examples the method comprises attaching a second glass preform to a fourth region of the routing structure, the second glass preform also comprising an optical waveguide. The method comprises attaching a second photonic IC (PIC) die over a fifth region of the routing structure, adjacent to the second glass preform. The method comprises attaching a second electronic integrated circuit (EIC) die over a sixth region of the routing structure, adjacent to the second PIC die. The method comprises attaching a second vertical optical coupler to the second glass substrate, the second glass substrate comprising another optical waveguide optically coupled to the second PIC die through the second vertical optical coupler.

However, the above embodiments are not limited in this regard, and, in various implementations, the above embodiments may include the undertaking of only a subset of such features, undertaking a different order of such features, undertaking a different combination of such features, and/or undertaking additional features than those features explicitly listed. The scope of the disclosure should therefore be determined with reference to the appended claims, along with the full scope of equivalents to which such claims are entitled.

What is claimed is:

1. An integrated circuit (IC) device, comprising:
a routing structure on a first side of a substrate, the routing structure comprising metallization features;
a plurality of electronic IC (EIC) die over the first side of the substrate and electrically interconnected to each other by the routing structure;
a photonic IC (PIC) die over the first side of the substrate, the PIC die optically coupled to a first end of an optical waveguide; and
a plurality of through vias extending through the substrate from the routing structure to a second side of the substrate, the routing structure electrically coupling the through vias to at least one of the plurality of EIC die.

2. The IC device of claim 1, wherein:
a glass preform affixed to the first side of the substrate comprises the optical waveguide; and
a first of the plurality of EIC die attached to the first side of the substrate is adjacent to the glass preform; and
the PIC die is attached to the first of the plurality of EIC die, and is in alignment with an end coupler of the optical waveguide.

3. The IC device of claim 2, wherein:
the PIC die is one of a plurality of PIC die arrayed along a first dimension of the routing structure and coupled to an optical waveguide embedded within the glass preform; and
each of the plurality of PIC die is adjacent to one of the plurality EIC die, which are arrayed along a second dimension of the routing structure.

4. The IC device of claim 2, further comprising first solder features between the PIC die and the first of the plurality of EIC die.

5. The IC device of claim 4, further comprising second solder features between metallization features of the routing structure and each of the plurality of EIC die.

6. The IC device of claim 1, wherein:
the substrate comprises glass;
the through vias extend through a thickness of the glass;
the metallization features are embedded within an organic dielectric material; and
the each of the plurality of EIC die is coupled to the routing structure either through a direct bond or through solder features.

7. The IC device of claim 1, wherein:
the first side of the substrate comprises a recess;
a passive device is within the recess, between the routing structure and the second side of the substrate; and
the passive device is electrically coupled to the routing structure.

8. The IC device of claim 7, wherein the passive device comprises a coupling capacitor with one or more terminals coupled to the routing structure and one or more terminals coupled to the second side of the substrate by one or more of the through vias.

9. The IC device of claim 1, wherein the substrate is a first substrate, the routing structure is a first routing structure, the optical waveguide is a first optical waveguide, and the IC device further comprises:
a second substrate coupled to the second side of the first substrate, wherein the second substrate comprises glass and a second optical waveguide embedded within the glass;
a second routing structure on a first side of the second substrate, the second routing structure comprising metallization features electrically interconnected to a second end of the through vias and to a first end of a plurality of second through vias extending through the second substrate to a second side of the second substrate; and
a vertical optical coupler embedded within a recess in the first side of the second substrate, the vertical optical coupler optically coupling a first end of the second optical waveguide to a second end of the first optical waveguide.

10. The IC device of claim 9, wherein:
the first substrate is one of a plurality of first substrates coupled to the second routing structure;
the vertical optical coupler is one of a plurality of vertical optical couplers, each of the vertical optical couplers embedded within one of a plurality of recesses in the first side of the second substrate;
each of the plurality of first substrates comprises a PIC die and an EIC die, and
each PIC die is coupled to a corresponding one of the plurality of vertical optical couplers.

11. The IC device of claim 9, wherein a second end of the second optical waveguide is coupled to an optical connector affixed to the second substrate.

12. The IC device of claim 9, further comprising a memory IC die attached to at least one of the routing structure, or the second routing structure.

13. An integrated circuit (IC) device, comprising:
a first substrate comprising glass and an optical waveguide embedded within the glass;
a first routing structure on a first side of the first substrate, the first routing structure comprising metallization features electrically interconnected to a first plurality of conductive through vias extending through the first substrate to a second side of the first substrate;
a second substrate coupled to the first routing structure, the second substrate comprising:
a second plurality of conductive through vias extending through the second substrate; and
a second routing structure on a side of the second substrate opposite the first routing structure, the second routing structure coupled to the first routing structure through the second plurality of through vias;
an electronic IC (EIC) die electrically coupled to the second routing structure; and
a photonic IC (PIC) die coupled to the optical waveguide through a vertical optical coupler embedded within a recess in the first side of the first substrate.

14. The IC device of claim 13, wherein:
a glass preform affixed to the second substrate comprises a second optical waveguide coupling the vertical optical coupler to the PIC die;
the EIC die is a first EIC die; and
a second EIC die attached to the second substrate is between the first EIC die and the glass preform; and
the PIC die is attached to the second EIC die, in alignment with an end coupler of the second optical waveguide.

15. The IC device of claim 14, wherein:
the second substrate comprises glass;
the first and second routing structures comprise metallization features embedded within an organic dielectric material; and
the first and second EIC die are coupled to the second routing structure either through a direct bond or through solder features.

16. The IC device of claim 14, wherein:
the PIC die is one of a plurality of PIC die arrayed along a first dimension of the second routing structure and coupled to an optical waveguide embedded within the glass preform; and
each of the plurality of PIC die is adjacent to one of a plurality EIC die arrayed along a second dimension of the second routing structure.

17. The IC device of claim 14, further comprising:
first solder features between the first routing structure and the second through vias;
second solder features between the second routing structure and each of the first EIC die and the second EIC die; and
third solder features between the PIC die and the second EIC die.

18. A method comprising:
receiving a workpiece comprising glass substrate;
forming through holes in the glass substrate and forming conductive through vias by metallizing the through holes;
building up a routing structure coupled to the through vias; and
attaching a glass preform to a first region of the routing structure, the glass preform comprising an optical waveguide;
attaching a photonic IC (PIC) die over a second region of the routing structure, adjacent to the glass preform; and
attaching an electronic integrated circuit (EIC) die over a third region of the routing structure, adjacent to the PIC die.

19. The method of claim 18, further comprising:
attaching a vertical optical coupler to a second glass substrate, the second glass substrate comprising a second optical waveguide and a second routing structure; and
attaching the through vias to the second routing structure with the optical waveguide optically coupled to the vertical optical coupler.

20. The method of claim 19, further comprising:
attaching a second glass preform to a fourth region of the routing structure, the second glass preform also comprising an optical waveguide;
attaching a second photonic IC (PIC) die over a fifth region of the routing structure, adjacent to the second glass preform;
attaching a second electronic integrated circuit (EIC) die over a sixth region of the routing structure, adjacent to the second PIC die; and
attaching a second vertical optical coupler to the second glass substrate, the second glass substrate comprising another optical waveguide optically coupled to the second PIC die through the second vertical optical coupler.
